(19) United States
(12) Patent Application Publication
(10) Pub. No.: US 2017/0012029 A1
(43) Pub. Date: Jan. 12, 2017

(54) TSV-CONNECTED BACKSIDE DECOUPLING

(71) Applicant: INTEL CORPORATION, Santa Clara, CA (US)

(72) Inventors: William J. LAMBERT, Chandler, AZ (US); Robert L. SANKMAN, Phoenix, AZ (US); Tyler N. OSBORN, Gilbert, AZ (US); Charles A. GEALER, Phoenix, AZ (US)

(21) Appl. No.: 15/117,708

(22) PCT Filed: Mar. 28, 2014
(86) PCT No.: PCT/US2014/032263

§ 371 Date: Aug. 9, 2016

(51) Int. Cl. H01L 25/11; H01L 25/00; H01L 25/065; H01L 23/48; H01L 49/02

(52) U.S. Cl. CPC H01L 25/117; H01L 23/481; H01L 28/40; H01L 25/0657; H01L 25/50; H01L 2225/06513; H01L 2225/06517

(57) ABSTRACT

An apparatus including a die including a plurality of through silicon vias (TSV's) extending from a device side to a backside of the die; and a decoupling capacitor coupled to the TSV's. A method including providing a die including a plurality of through silicon vias (TSV's) extending from a device side to a backside of the die; coupling a decoupling capacitor to the backside of the die. An apparatus including a computing device including a package including a microprocessor including a device side and a backside with through silicon vias (TSV's) extending from the device side to the backside, and a decoupling capacitor coupled to the backside of the die; and a printed circuit board, wherein the package is coupled to the printed circuit board.

### BACKGROUND

Field

Integrated circuit structures.

Description of Related Art

Current microprocessors are capable of generating large load transients that occur in a very short amount of time, often faster than 10 nanoseconds (ns). In order to avoid voltage droops that could lead to an execution error, microprocessor power delivery networks generally contain high frequency decoupling capacitor(s) robustly connected adjacent to the microprocessor die or integrated into the die itself. This will tend to become more difficult for future process nodes, as device density is expected to increase significantly, while the magnitude and speed of the load transients is expected to stay approximately the same. Respectively, the same amount of power delivery decoupling will be required in an area shrinking by about 50 percent for each new process node. Two solutions (sometimes combined) are in common usage on past and current products. The first is to place multiple ceramic capacitors on the die side, on the land side, or embedded in the package substrate. The capacitors are connected to the die using wide power planes or through a dense array of plated through holes (PTHs). This provides a large amount of decoupling capacitance, but the response speed is fundamentally limited by the physical distance of the capacitors from the die and the area of the die to which they are connected, which will reduce the effectiveness at future process nodes and lead to larger voltage droops. The second solution is metal-insulator-metal (MIM) capacitors implemented on the die. MIM capacitors respond almost immediately to local load transients but have limited charge storage capacity. Ideally, MIM density would scale inversely to device density, but this has proven challenging in practice so there is a tendency to keep MIM density constant.

### BRIEF DESCRIPTION OF THE DRAWINGS

FIG. 1 shows a cross-sectional side view of an embodiment of a package assembly including a die with through silicon via (TSV) with a MIM capacitor connected to a backside of the die.

FIG. 2 shows a top view of structure of FIG. 1.

FIG. 3 shows a cross-sectional side view of another embodiment of a package assembly including a die and a decoupling capacitor connected to the die.

FIG. 4 shows a cross-sectional side view another embodiment of a package assembly including a die and a decoupling capacitor connected to a backside of the die.

FIG. 5 illustrates an embodiment of a computing device.

### DETAILED DESCRIPTION

An apparatus including a through silicon via (TSV) die and at least one decoupling capacitor connected to the TSV's is described as a package structure and computing device incorporating such an apparatus as well as a method of connecting a decoupling capacitor to a backside of a die (e.g., a TSV die). Embodiments include a decoupling capacitor for a microprocessor (or chipset) implemented on a back of a die and connected with TSV's. Die thinning to die thickness representatively on the order of 100 microns generally means that a length of the individual TSV's will be small, so an array of TSV's will have relatively low inductance allowing for very fast transient response. Embodiments include capacitor(s) on the backside of the die implemented as a MIM capacitor layer on the back of the die itself (constructed similarly to a backside redistribution layer); an array capacitor mounted on top of the die; or using MIM or device capacitor implemented on a stacked die (for example, using a MIM layer added to a memory die). The embodiments described provide a significant increase in decoupling capacitance that is effective at very high speeds, to result in equal or decreased voltage droop for future process nodes without requiring expensive MIM scaling.

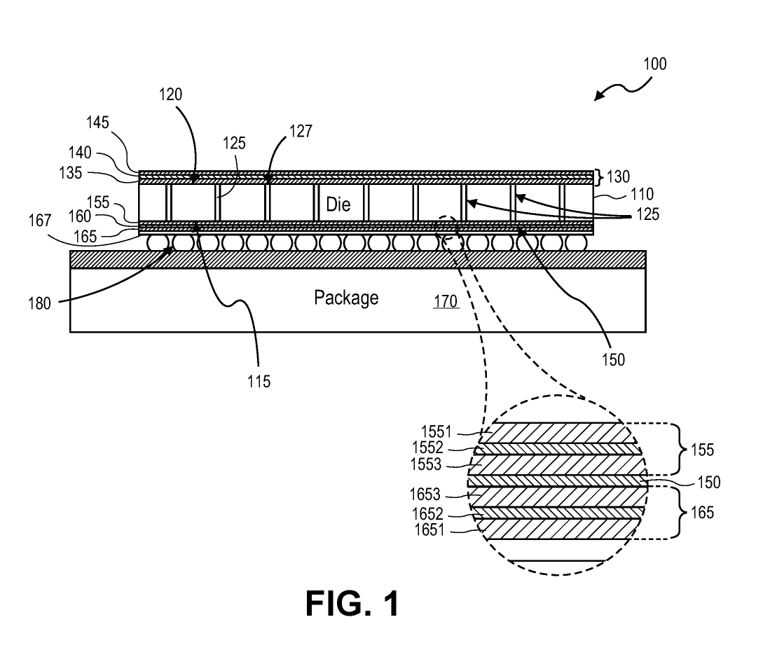

FIG. 1 shows an embodiment of a package assembly including a TSV die with a MIM capacitor connected to a backside of the die and a backside metallization/distribution layer used as a conductive layer of the MIM. Referring to FIG. 1, structure 100 includes die 110 having device side 115 and backside 120. In this embodiment, die 110 is a TSV die including TSV 125 extending from device side 115 to backside 120 and defining contact points 127 on the backside. Contact points provide connection points for a device, such as, in this embodiment, a MIM capacitor. A contact point may be positioned at a location of a respective TSV. Alternatively, a conductive metallization or distribution layer (e.g., copper traces) may be present to transfer a position of one or more contact points in an area associated with backside 120 of die 110 for connection to a device. Connecting a device such as a decoupling capacitor (e.g., a MIM capacitor) directly to contact points defined by TSV's includes connecting such capacitor to contact points that are positioned at a location of the respective TSV's or that are routed to a different position on backside 120 through a metallization layer. In this embodiment, connected to a portion of the contact points on backside 120 of die 110 is a MIM capacitor. More specifically, MIM capacitor 130 consists of metal layer 135 of, for example, copper, insulator 140 of, for example, a dielectric material having a dielectric constant greater than silicon dioxide (“a high k dielectric material”), such as a hafnium-based dielectric (e.g., hafnium oxide); and metal layer 145 of, for example, copper. In one embodiment, metal layer 135 is introduced in a backside metallization process by, for example, forming a pattern and introducing a copper material by, for example, electroless depositing a seed material followed by electroplating a copper metal on the exposed seed areas. Insulator 140 may be formed by deposition (e.g., chemical vapor deposition). Metal layer 145 may be formed by the copper introduction process described with respect to metal layer 135. MIM 130 on the backside of the die may occupy a portion of the area of the backside of the die including an entire portion. In one embodiment, in addition to MIM 130 on backside 120 of die 110, there may be other devices connected to contact points 127 and TSV's 125, either adjacent to MIM 130 or above MIM 130 (e.g., connected through a routing interconnect through MIM 130).

FIG. 1 also shows MIM 150 on device side 115 of die 110. In one embodiment, MIM 150 includes metal layer 155 of, for example, copper; dielectric layer 160 of, for example, a high k dielectric (e.g., hafnium oxide); and metal layer 165 of, for example, copper. MIM 150, in one embodiment, may be formed in the ultimate metal layer (N) of the device side as a metal layer 165 with connection to the penultimate metal layer (N-1) through, for example, separate conductive vias between the penultimate metal layer and each of metal layer 155 and metal layer 165 according to a similar process as used to form MIM 130. As with MIM 130, MIM 150 may occupy a portion of device side 115 of die 110, including the entire portion. Disposed on metal layer 165 is a dielectric layer (not shown) and conductive contact points. In one embodiment, device interconnects may extend from device side 115 of die 110 through metal layer 165 of MIM 150 to the contact pads. Such interconnects as they extend through MIM 150 are electronically isolated from MIM 150. Optionally, a conductive metallization or distribution layer (e.g., copper traces) connected to the interconnects may then be disposed on the dielectric layer on metal layer 165. The metallization layer serves to position contact points for connection to another substrate, such as package 170. FIG. 1 shows outer passivation layer 167 of a dielectric material that covers any metallization layer (e.g., copper traces) and has openings to contact pads to allow connection of such interconnections to solder connections 180. As illustrated in FIG. 1, die 110 is connected to package 170 through, in this embodiment, solder connections 180.

An inset of FIG. 1 shows another embodiment of MIM 150. In this embodiment, MIM 150 may be formed by depositing a dielectric layer (dielectric layer 1552) on ultimate metal layer 155 followed by a layer of tantalum metal (layer 1553), MIM dielectric layer 150, second tantalum layer (layer 1653), dielectric layer 1652 and copper layer 1651. Conductive vias are separately formed to layer 1553 and layer 1653. A similar configuration and process may be used to form MIM 130 on a backside of die 110.

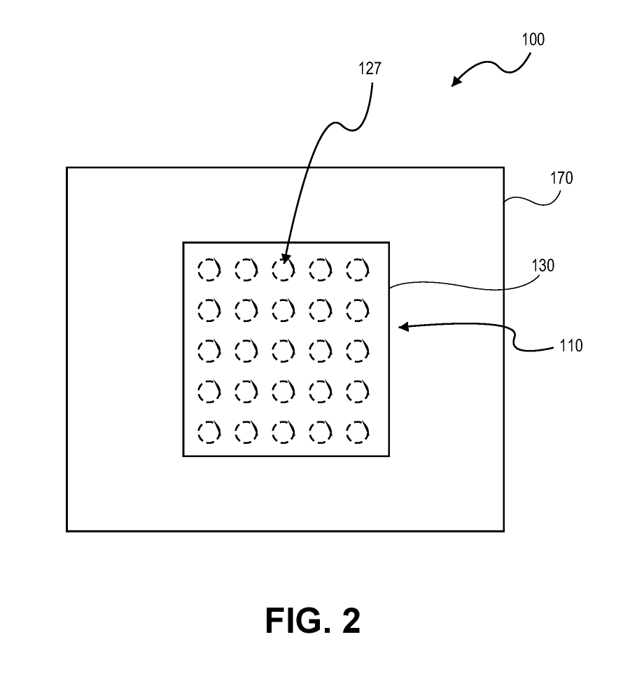

FIG. 2 shows a top view of structure 100 of FIG. 1. FIG. 2 shows die 110 connected to package 170 and illustrates contact points 127 associated with respective TSV's 125 connected to MIM 130.

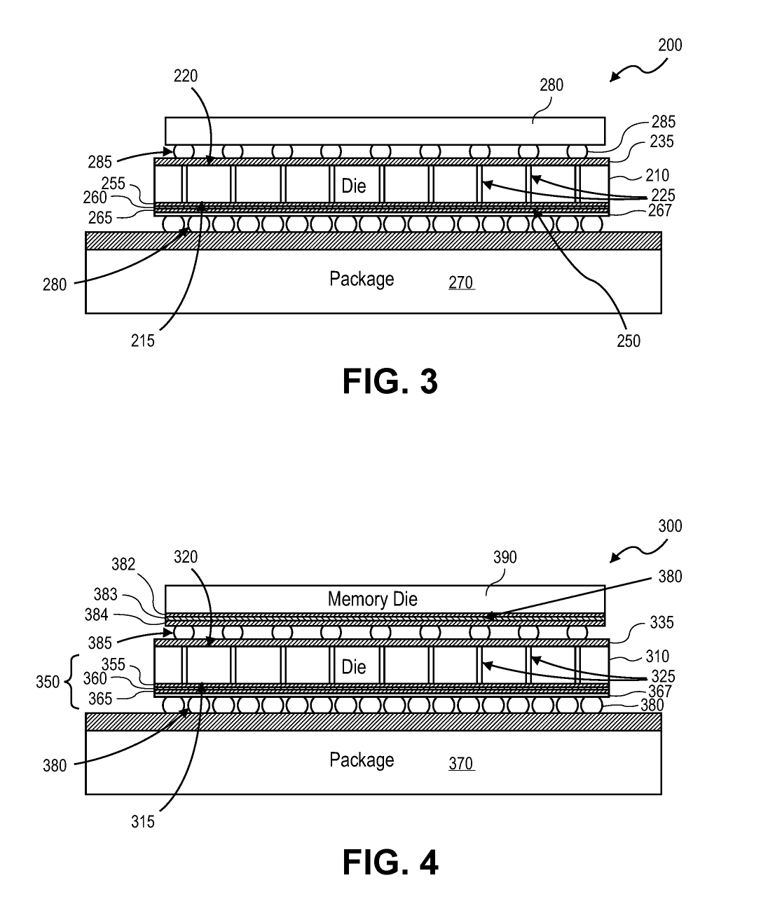

FIG. 3 shows a cross-sectional side view of another embodiment of a package including a die and a decoupling capacitor connected to the die, the die and decoupling capacitor in turn connected to a package substrate. In this embodiment, the decoupling capacitance is implemented by an array capacitor mounted on a backside of the die. Referring to FIG. 3, assembly 200 includes die 210 having device side 215 and backside 220. Die 210 also includes TSV's 225 extending from device side 215 to backside 220 and connected to or defining contact points on the backside.

On device side 215 of die 210 is MIM 250. MIM 250 includes first conductive layer 255 of, for example, copper; dielectric layer 260 of silicon oxide, silicon nitride, or other common dielectric layers used in semiconductor fabrication; and conductive layer 265 of, for example, copper. MIM 250 is disposed on a portion of device side 215, including an entire portion and may be formed as described with reference to a MIM capacitor in FIG. 1. Conductive vias may extend through MIM 250 to metallization layer 267 that defines contact points for connection to solder connections 280 to connect die to package 270. On backside 220 of die 210, contact points defined by TSV's 225 serve to connect the die to ceramic array capacitor 280 through solder connections 285 to metallization layer 235 formed, for example, as a patterned copper layer through a plating process. In one embodiment, the array capacitor uses a ball grid array (BGA) of interleaved ground and V_{cc} bumps. In this manner, any excess inductance that is problematic with two terminal capacitors is reduced or eliminated.

FIG. 4 shows a cross-sectional side view another embodiment of an assembly including a die and a decoupling capacitor connected to a backside of the die. Referring to FIG. 4, assembly 300 includes die 310, including device side 315 and backside 320. Die 310 includes TSV's 325 extending from a device side to backside 320 and connecting to or defining contact points on the backside of the die to patterned distribution (conductive) layer 335. Connected to device side 315 of die 310 is MIM 350. MIM 350 includes conductive layer 355 of, for example, copper, connected to contact points on the die; dielectric layer 360 of, for example, hafnium oxide; and conductive layer 365 of, for example, copper. MIM 350 extends over a portion of device side 315 of die 310, including an entire portion and may be formed as described above with respect to MIM 150 in FIG. 1. Disposed on conductive layer 365 is a dielectric layer (not shown) and contact pads (copper contact pads) and, optionally, conductive (e.g., copper) traces as a metallization or distribution layer. FIG. 4 shows outer passivation layer 367 of a dielectric material that covers any metallization layer (e.g., copper traces) and has openings to the contact pads so that solder connections 380 can make electrical contact with the contact pads. Solder connections 380 connect die 310 to package 370.

On backside 320 of die 310 is memory die 390. Memory 390, in this embodiment, includes MIM 380, including conductive layer 382 of, for example, copper; dielectric layer 383 of, for example, hafnium oxide; and conductive layer 384 of, for example, copper or aluminum. MIM 380 may be formed as described above with respect to, for example, MIM 130 in FIG. 1. Memory die 390, including MIM 380, is connected to die 310 through solder connections 385.

Device size scaling without complimentary power scaling has made high-speed load transience a performance limiter. The embodiments described can significantly mitigate problems related to high-speed load transience, allowing products to operate at lower voltages (for lower power operation to increase battery life or to operate much more aggressive settings for improved peak performance).

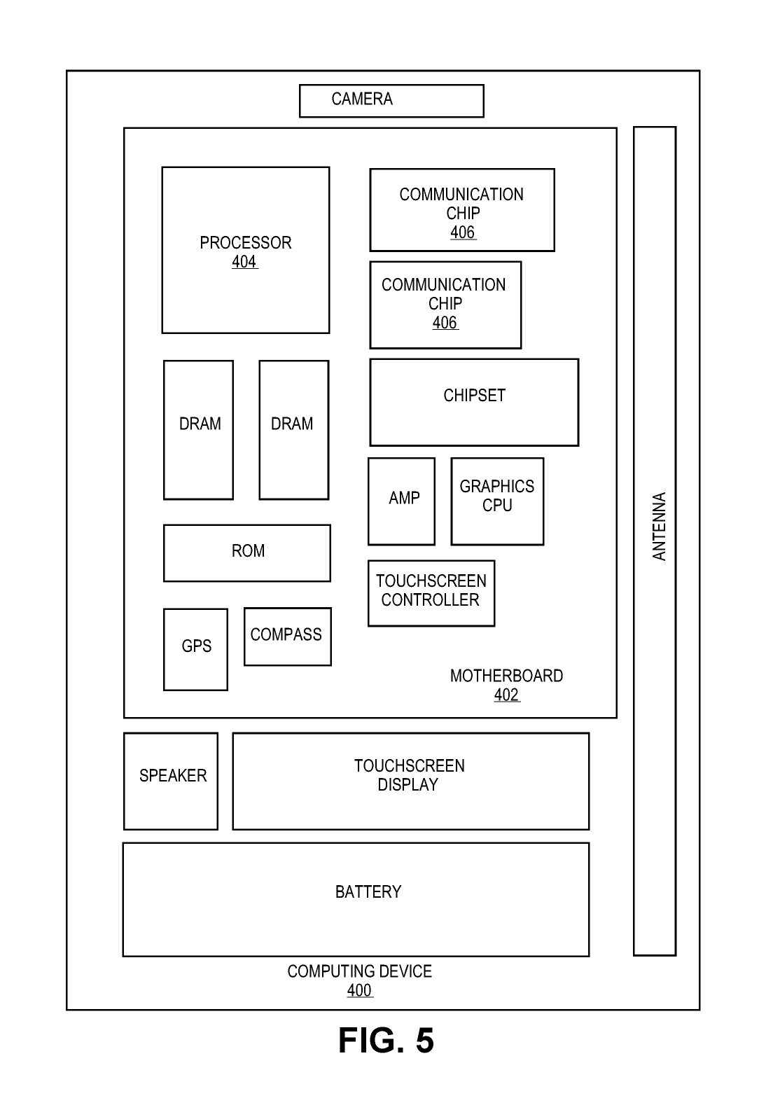

FIG. 5 illustrates computing device 400 in accordance with one implementation. Computing device 400 houses board 402. Board 402 may include a number of components, including but not limited to processor 404 and at least one communication chip 406. Processor 404 is physically and electrically coupled to board 402. In some implementations at least one communication chip 406 is also physically and electrically coupled to board 402. In further implementations, communication chip 406 is part of processor 404.

Depending on its applications, computing device 400 may include other components that may or may not be physically and electrically coupled to board 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

Communication chip 406 enables wireless communications for the transfer of data to and from computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. Communication chip 406 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 400 may include a plurality of communication chips 406. For instance, first communication chip 406 may be dedicated to shorter range wireless communications such as Wi-Fi and Bluetooth and second communication chip 406 may be dedicated to longer range wireless communications such as GPS, EDGE, GPRS, CDMA, WiMAX, LTE, Ev-DO, and others.

Processor 404 of computing device 400 includes an integrated circuit die packaged referred to as processor 404. In some implementations of the invention, the integrated circuit die of the processor is a die incorporating TSV's and is connected to one or more passives, such as MIM capacitors and/or decoupling capacitors in a manner such as described above. The term “processor” may refer to any device or portion of a device that processes electronic data from registers and/or memory to transform that electronic data into other electronic data that may be stored in registers and/or memory.

Communication chip 406 also includes an integrated circuit die packaged within communication chip 406. In accordance with another implementation, the integrated circuit die of the communication chip is a die incorporating TSV's and is connected to one or more passives, such as MIM capacitors and/or decoupling capacitors in a manner such as described above.

In further implementations, another component housed within computing device 400 may contain an integrated circuit die of the communication chip that is a doe incorporating TSV's and is connected to one or more devices, such as MIM capacitors and/or decoupling capacitors in a manner such as described above.

In various implementations, computing device 400 may be a laptop, a netbook, a notebook, an ultrabook, a smartphone, a tablet, a personal digital assistant (PDA), an ultra mobile PC, a mobile phone, a desktop computer, a server, a printer, a scanner, a monitor, a set-top box, an entertainment control unit, a digital camera, a portable music player, or a digital video recorder. In further implementations, computing device 400 may be any other electronic device that processes data.

### EXAMPLES

Example 1 is an apparatus including a die including a plurality of through silicon vias (TSV's) extending from a device side to a backside of the die; and a decoupling capacitor coupled to the TSV's.

In Example 2, the decoupling capacitor in the apparatus of Example 1 includes a metal-insulator-metal (MIM) capacitor.

In Example 3, the TSV's in the apparatus of Example 1 define contact points on the backside of the die and the MIM capacitor includes a metal layer coupled directly to the contact points.

In Example 4, the apparatus of Example 2 further includes a secondary die, wherein the MIM capacitor is formed on the secondary die.

In Example 5, the TSV's in the apparatus of Example 4 define contact points on the backside of the die and a metal layer of the MIM capacitor is coupled to the contact points.

In Example 6, the first layer of the MIM capacitor in the apparatus of Example 5 is coupled to the contact points through solder connections.

In Example 7, the TSV's in the apparatus of Example 1 define contact points on the backside of the die and the decoupling capacitor includes a ceramic array capacitor coupled to the contact points.

In Example 8, the ceramic array capacitor in the apparatus of Example 7 is coupled to the contact points through solder connections.

In Example 9, the apparatus in Example 1 further includes a metal-insulator-metal (MIM) capacitor positioned to a device side of the die.

Example 10 is a method including providing a die including a plurality of through silicon vias (TSV's) extending from a device side to a backside of the die; and coupling a decoupling capacitor to the backside of the die.

In Example 11, the decoupling capacitor in the method of Example 10 includes a metal-insulator-metal (MIM) capacitor.

In Example 12, the TSV's in the method of Example 10 define contact points on the backside of the die and coupling the MIM capacitor includes coupling a metal layer of the MIM directly to the contact points.

In Example 13, coupling a decoupling capacitor to the backside of the die in the method of Example 11 includes coupling a secondary die to the backside of the die and the MIM capacitor is formed on the secondary die.

In Example 14, the TSV's in the method of Example 13 define contact points on the backside of the die and a metal layer of the MIM capacitor is coupled to the contact points.

In Example 15, the metal layer of the MIM capacitor in the method of Example 14 is coupled to the contact points through solder connections.

In Example 16, the TSV's in the method of Example 10 define contact points on the backside of the die and the decoupling capacitor includes a ceramic array capacitor and coupling to the backside of the die includes coupling the ceramic array capacitor to the contact points.

In Example 17, the ceramic array capacitor in the method of Example 16 is coupled to the contact points through solder connections.

In Example 18, the method in Example 10 further includes coupling a metal-insulator-metal (MIM) capacitor to a device side of the die.

Example 19 is an apparatus including a computing device including a package including a microprocessor including a device side and a backside with through silicon vias (TSV's) extending from the device side to the backside, and a decoupling capacitor coupled to the backside of the die; and a printed circuit board, wherein the package is coupled to the printed circuit board.

In Example 20, the decoupling capacitor in the apparatus of Example 19 includes a metal-insulator-metal (MIM) capacitor.

In Example 21, the TSV's in the apparatus of Example 20 define contact points on the backside of the die and the MIM capacitor includes a metal layer coupled directly to the contact points.

In Example 22, the apparatus of Example 20 further includes a secondary die, wherein the MIM capacitor is formed on the secondary die.

In Example 23, the TSV's in the apparatus of Example 22 define contact points on the backside of the die and a metal layer of the MIM capacitor is coupled to the contact points.

In Example 24, the first layer of the MIM capacitor in the apparatus of Example 23 is coupled to the contact points through solder connections.

Example 25, the TSV's in the apparatus of Example 19 define contact points on the backside of the die and the decoupling capacitor includes a ceramic array capacitor coupled to the contact points.

In Example 26, the ceramic array capacitor in the apparatus of Example 19 is coupled to the contact points through solder connections.

In Example 27, the apparatus in Example 19 further includes a metal-insulator-metal (MIM) capacitor connected to the device side of the microprocessor.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

1. An apparatus comprising:
a die comprising a plurality of through silicon vias (TSV's) extending from a device side to a backside of the die; and
a decoupling capacitor coupled to the TSV's.

2. The apparatus of claim 1, wherein the decoupling capacitor comprises a metal-insulator-metal (MIM) capacitor.

3. The apparatus of claim 2, wherein the TSV's define contact points on the backside of the die and the MIM capacitor comprises metal-dielectric-metal layers coupled directly to the contact points.

4. The apparatus of claim 2, further comprising a secondary die, wherein the MIM capacitor is formed on the secondary die.

5. The apparatus of claim 4, wherein the TSV's define contact points on the backside of the die and a metal layer of the MIM capacitor is coupled to the contact points.

6. The apparatus of claim 5, wherein the first layer of the MIM capacitor is coupled to the contact points through solder connections.

7. The apparatus of claim 1, wherein the TSV's define contact points on the backside of the die and the decoupling capacitor comprises a ceramic array capacitor coupled to the contact points.

8. The apparatus of claim 7, wherein the ceramic array capacitor is coupled to the contact points through solder connections.

9. The apparatus of claim 1, further comprising a metal-insulator-metal (MIM) capacitor positioned to a device side of the die.

10. A method comprising:
providing a die comprising a plurality of through silicon vias (TSV's) extending from a device side to a backside of the die; and
coupling a decoupling capacitor to the backside of the die.

11. The method of claim 10, wherein the decoupling capacitor comprises a metal-insulator-metal (MIM) capacitor.

12. The method of claim 11, wherein the TSV's define contact points on the backside of the die and coupling the MIM capacitor comprises coupling a metal layer of the MIM directly to the contact points.

13. The method of claim 11, wherein coupling a decoupling capacitor to the backside of the die comprises coupling a secondary die to the backside of the die and the MIM capacitor is formed on the secondary die.

14. The method of claim 13, wherein the TSV's define contact points on the backside of the die and a metal layer of the MIM capacitor is coupled to the contact points.

15. The method of claim 14, wherein the metal layer of the MIM capacitor is coupled to the contact points through solder connections.

16. The method of claim 10, wherein the TSV's define contact points on the backside of the die and the decoupling capacitor comprises a ceramic array capacitor and coupling to the backside of the die comprises coupling the ceramic array capacitor to the contact points.

17. The method of claim 16, wherein the ceramic array capacitor is coupled to the contact points through solder connections.

18. The method of claim 10, further comprising coupling a metal-insulator-metal (MIM) capacitor to a device side of the die.

19. An apparatus comprising:
a computing device comprising a package comprising:
a microprocessor comprising a device side and a backside with through silicon vias (TSV's) extending from the device side to the backside, and
a decoupling capacitor coupled to the backside of the die; and
a printed circuit board, wherein the package is coupled to the printed circuit board.

20. The apparatus of claim 19, wherein the decoupling capacitor comprises a metal-insulator-metal (MIM) capacitor.

21. The apparatus of claim 20, wherein the TSV's define contact points on the backside of the die and the MIM capacitor comprises a metal layer coupled directly to the contact points.

22. The apparatus of claim 20, further comprising a secondary die, wherein the MIM capacitor is formed on the secondary die.

23. The apparatus of claim 22, wherein the TSV's define contact points on the backside of the die and a metal layer of the MIM capacitor is coupled to the contact points.

24. The apparatus of claim 23, wherein the first layer of the MIM capacitor is coupled to the contact points through solder connections.

25. The apparatus of claim 19, wherein the TSV's define contact points on the backside of the die and the decoupling capacitor comprises a ceramic array capacitor coupled to the contact points.

26. The apparatus of claim 25, wherein the ceramic array capacitor is coupled to the contact points through solder connections.

27. The apparatus of claim 19, further comprising a metal-insulator-metal (MIM) capacitor coupled to the device side of the microprocessor.
